(19) United States
(12) Patent Application Publication
(10) Pub. No.: US 2011/0304366 A1
(43) Pub. Date: Dec. 15, 2011

(54) PLL CIRCUIT

(76) Inventors: Tadayuki Kanda, Osaka (JP); Akira Kawabe, Osaka (JP)

(21) Appl. No.: 13/014,370

(22) Filed: Jan. 26, 2011

(30) Foreign Application Priority Data
Jun. 11, 2010 (JP) 2010-133540

(51) Int. Cl. H03L 7/06

(52) U.S. Cl. 327/157

(57) ABSTRACT

A PLL circuit comprises a phase frequency detector configured to output a phase frequency difference signal with a pulse duration according to a phase difference and a frequency difference between a reference clock signal and a feedback clock signal according to an output clock signal; a charge pump circuit configured to output a charge pump current which is an output current according to the phase frequency difference signal and reduce a charge pump current amount in accordance with a charge pump current amount control signal for reducing the charge pump current amount stepwisely; and a lock detecting unit configured to detect whether or not the feedback clock signal is locked to the reference clock signal and output a lock detection signal when detecting a lock of the reference clock signal and the feedback clock signal

### RELATED APPLICATIONS

The disclosure of Japanese Patent Application No. 2010-133540 filed on Jun. 11, 2010 including specification, drawings and claims is incorporated herein by reference in its entirety.

### BACKGROUND ART

1. Field of the Invention

The present invention relates to a PLL (phase locked loop) circuit.

2. Description of the Related Art

A conventional PLL circuit will be described with reference to FIG. 8. Referring to FIG. 8, the PLL circuit includes a phase frequency detector 701, a charge pump circuit 702, a low pass filter 703, a voltage controlled oscillator 704, and a frequency divider 705.

The phase frequency detector 701 detects a phase difference and a frequency difference between a reference clock signal FREF and a feedback clock signal FDIV according to an output clock signal FVCO, and outputs an up-pulse signal UP and a down-pulse signal DOWN for controlling a charge pump circuit 702 in accordance with the phase difference and the frequency difference. To be specific, when a phase of the feedback clock signal FDIV is delayed with respect to a phase of the reference clock signal FREF, or a frequency of the feedback clock signal FDIV is lower than a frequency of the reference clock signal FREF, the phase frequency detector 701 outputs the up-pulse signal UP with a pulse duration according to a phase difference and a frequency difference for increasing the frequency of the feedback clock signal FDIV. On the other hand, when a phase of the feedback clock signal FDIV is put forward with respect to a phase of the reference clock signal FREF, or a frequency of the feedback clock signal FDIV is higher than a frequency of the reference clock signal FREF, the phase frequency detector 701 outputs a down-pulse signal DOWN with a pulse duration according to a phase difference and a frequency difference for decreasing the frequency of the feedback clock signal FDIV.

The charge pump circuit 702 outputs a charge pump current ICPO according to the up-pulse signal UP or the down-pulse signal DOWN output from the phase frequency detector 701. A low pass filter 703 smoothes a charge pump current ICPO from the charge pump circuit 702 and outputs an analog voltage signal VCONT. The voltage controlled oscillator 704 outputs the output clock signal FVCO with an oscillating frequency determined according to the analog voltage signal VCONT from the low pass filter 703. The frequency divider 705 generates the feedback clock signal FDIV by dividing a frequency of the output clock signal FVCO by a desired frequency dividing number and feeds it back to the phase frequency detector 701. This results in the output clock signal FVCO which is synchronous in phase with the reference clock signal FREF and has a frequency obtained by multiplying the frequency of the reference clock signal FREF by an inverse number of the frequency dividing number.

To improve performance of the PLL circuit, it is necessary to reduce a lock-up time which is a time from when a PLL operation starts until a lock is complete and reduce a reference leak (spurious) which negatively affects stability after the lock or a noise of the output clock signal. To reduce the lock-up time, the output current of the charge pump circuit may be increased, but the reference leak increases after the lock. On the other hand, to reduce the reference leak, the output current of the charge pump circuit may be reduced, but the lock-up time increases.

As should be appreciated from the above, reduction of the lock-up time and reduction of the reference leak have a trade-off relationship. Therefore, reduction of the lock-up time and reduction of the reference leak need to be implemented in a well-balanced manner. To this end, Japanese Laid-Open Patent Application Publication Nos. 1998-233681, and 1999-251902 disclose techniques as described below.

In the technique disclosed in Japanese Laid-Open Patent Application Publication No. 1998-233681, in a PLL circuit which is capable of switching a charge pump current, a pulse duration difference generator identifies a difference in pulse duration between an up-pulse signal and a down-pulse signal which are used for controlling the charge pump current, and the charge pump current is increased if the difference in pulse duration is large, while the charge pump current is decreased if the difference in pulse duration is small.

In the technique disclosed in Japanese Laid-Open Patent Application Publication No. 1999-251902, in a PLL circuit, a charge pump current is corrected based on a control voltage of a voltage controlled oscillator which is output from a low pass filter to prevent a loop gain and a damping factor from fluctuating.

### SUMMARY OF THE INVENTION

The techniques associated with the PLL circuit disclosed in Japanese Laid-Open Patent Application Publication Nos. 1998-233681, and 1999-251902 have drawbacks as described below.

In the PLL circuit disclosed in Japanese Laid-Open Patent Application Publication No. 1998-233681, a pulse duration difference detector is provided between a phase comparator and a charge pump circuit to detect a lock and switch a charge pump current. It is known that in design of the PLL circuit, a signal path between the phase comparator and the charge pump circuit is susceptible to a disturbance such as a noise and easily degrades its characteristic. Therefore, there is a chance that stability (e.g., jitter) of the PLL circuit after the lock is negatively affected. As a result, there is a possibility that the charge pump current cannot be switched properly.

In the PLL circuit disclosed in Japanese Laid-Open Patent Application Publication No. 1999-251902, the charge pump current is corrected in accordance with the control voltage of the voltage controlled oscillator. However, as shown in FIG. 9, in particular, a relationship between the control voltage and the oscillating frequency of the voltage controlled oscillator is susceptible to a temperature change, and the oscillating frequency changes under an equal control voltage. Therefore, there is a need for a control addressing the temperature change. Therefore, the charge pump current cannot be corrected properly according to the control voltage of the voltage controlled oscillator.

The above PLL circuits are designed such that the lock detecting unit and the control circuit are analog circuits. These circuits might be unstable due to an increase in a scale of the PLL circuit or a process variation.

The present invention has been developed in view of the above described configuration, and an object of the present invention is to provide a PLL circuit which can achieve reduction of the lock-up time and reduction of the reference leak in a well-balanced manner.

To achieve the above object, a PLL circuit of the present invention comprises a phase frequency detector configured to output a phase frequency difference signal with a pulse duration according to a phase difference and a frequency difference between a reference clock signal and a feedback clock signal according to an output clock signal; a charge pump circuit configured to output a charge pump current which is an output current according to the phase frequency difference signal and reduce a charge pump current amount in accordance with a charge pump current amount control signal for reducing the charge pump current amount stepwisely; a low pass filter configured to smooth the charge pump current and output a control voltage generated by smoothing the charge pump current; a voltage controlled oscillator configured to output the output clock signal with an oscillating frequency according to the control voltage; an analog/digital converter circuit configured to convert the control voltage of an analog signal into a digital signal and output the digital signal; a lock detecting unit configured to detect whether or not the feedback clock signal is locked to the reference clock signal and output a lock detection signal when detecting a lock of the reference clock signal and the feedback clock signal; a holding unit configured to hold the digital signal from the analog/digital converter circuit, when receiving the lock detection signal from the lock detecting unit as an input; and a charge pump control unit configured to generate the charge pump current amount control signal based on a result of comparison between the digital signal held in the holding unit at a point when the lock detection signal is input to the holding unit, and the digital signal output from the analog/digital converter circuit to the charge pump control unit, and output the charge pump current amount control signal to the charge pump circuit.

In accordance with this configuration, since the charge pump current amount remains unchanged until it is detected that the reference clock signal and the feedback clock signal are synchronized, reduction of the lock-up time is achieved. When it is detected that the reference clock signal and the feedback clock signal are synchronized, the charge pump current amount is reduced stepwisely, and thus reduction of the reference leak can be achieved. Thus, reduction of the lock-up time and reduction of the reference leak are achieved in a well-balanced manner.

In the PLL circuit, the charge pump control unit may include: a threshold generating unit configured to generate an upper limit threshold which is larger than a value of the digital signal held in the holding unit at a point when the lock detection signal is input to the holding unit, and a lower limit threshold smaller than the held value of the digital signal; a comparator unit configured to detect whether or not the digital signal output from the analog/digital converter circuit falls within a lock detection range from the lower limit threshold to the upper limit threshold; and a control signal generating unit configured to generate the charge pump current amount control signal for switching from a first current amount which is an initial current amount to a second current amount less than the first current amount, from when the comparator unit detects that the digital signal output from the analog/digital converter circuit reaches first the lock detection range.

In accordance with this configuration, since the lock detection range including the digital signal held in the holding unit at a time point when the PLL circuit is locked previously, is pre-set, a timing when the charge pump current amount is reduced (digital signal first reaches (falls into) the lock detection range) can be optimized to achieve reduction of the lock-up time and reduction of the reference leak in a well-balanced manner.

In the PLL circuit, the control signal generating unit may be configured to generate the charge pump current amount control signal for stepwisely reducing the charge pump current from an initial current amount to a current amount less than the initial current amount, every time the comparator unit detects that the digital signal from the analog/digital converter circuit falls outside the lock detection range or reaches the lock detection range, from when the comparator unit detects that the digital signal from the analog/digital converter circuit reaches first the lock detection range.

In accordance with this configuration, since the charge pump current amount is not rapidly reduced, but the charge pump current amount is gradually reduced according to the stabilization of the lock state of the PLL circuit, the operation of the PLL circuit can be more stabilized.

In the PLL circuit, the digital signal held in the holding unit at a point when the lock detection signal may be input to the holding unit is set arbitrarily.

With this configuration, an optimal timing when the charge pump current amount is reduced can be easily set.

The PLL circuit may further comprise a selector unit configured to select an outside lock detection signal from outside or the lock detection signal from the lock detecting unit in accordance with a predetermined select control signal, and output the selected lock detection signal to the holding unit.

In accordance with this configuration, the timing when the digital signal is held in the holding unit can be decided more flexibly using the outside lock detection signal or the lock detection signal output from the lock detecting unit in the PLL circuit.

In accordance with the present invention, it is possible to provide a PLL circuit which can achieve reduction of the lock-up time and reduction of the reference leak in a well-balanced manner.

The above and further objects, features and advantages of the present invention will more fully be apparent from the following detailed description of preferred embodiments with accompanying drawings.

### BRIEF DESCRIPTION OF THE DRAWINGS

FIG. 1 is a block diagram showing a configuration of a PLL circuit according to Embodiment 1 of the present invention.

FIG. 2 is a block diagram showing a configuration of a holding unit of FIG. 1.

FIG. 3 is a view showing a lock detecting method in a lock detecting unit of FIG. 2.

FIG. 4 is a block diagram showing a configuration of a control unit of FIG. 1.

FIG. 5 is a view showing a binary switching of a charge pump current amount by the charge pump control unit of FIG. 4.

FIG. 6 is a view showing a multi-valued switching of a charge pump current amount by a charge pump control unit in a PLL circuit according to Embodiment 2 of the present invention.

FIG. 7 is a block diagram showing a configuration of a holding unit in a PLL circuit according to Embodiment 4 of the present invention.

FIG. 8 is a block diagram showing a configuration of a conventional PLL circuit.

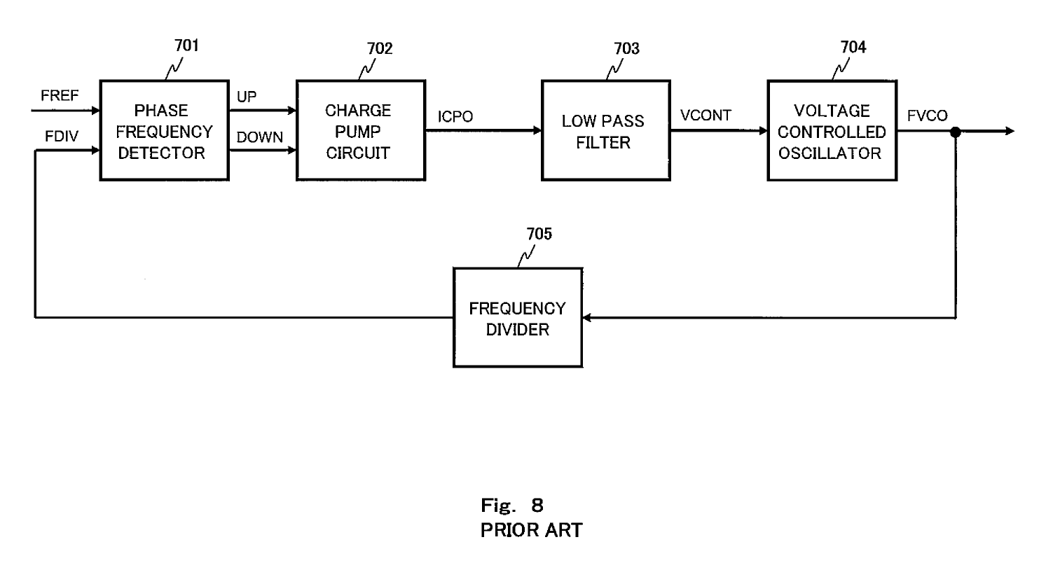

FIG. 9 is a graph showing a relationship between a VCO control voltage and an oscillating frequency in a conventional PLL circuit.

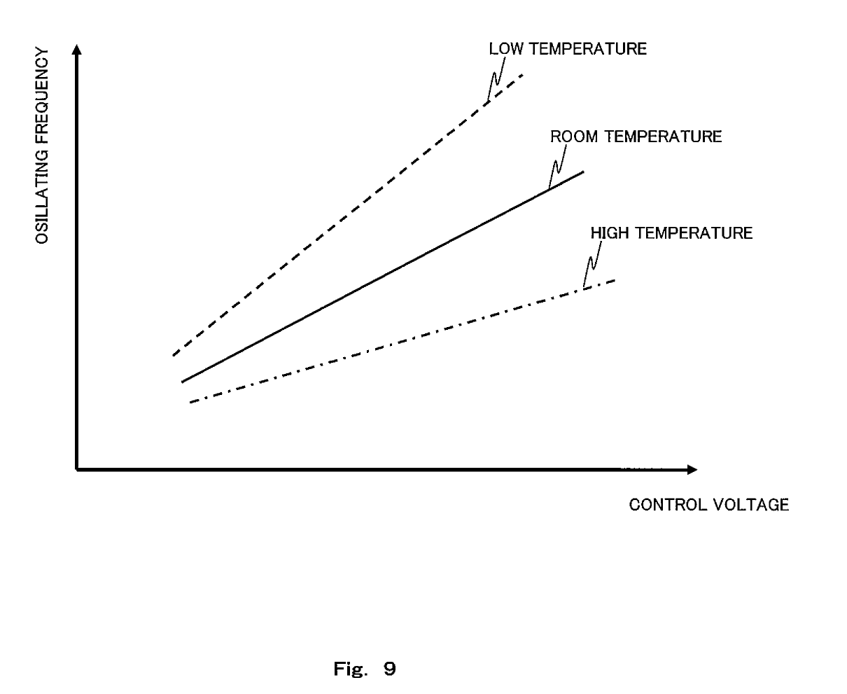

### DETAILED DESCRIPTION OF PREFERRED EMBODIMENTS

Hereinafter, preferred Embodiments of the present invention will be described with reference to the accompanying drawings. Throughout the drawings, the same reference numerals designate the same or corresponding constituents, which will not be described repetitively.

### Embodiment 1

### [PLL Circuit]

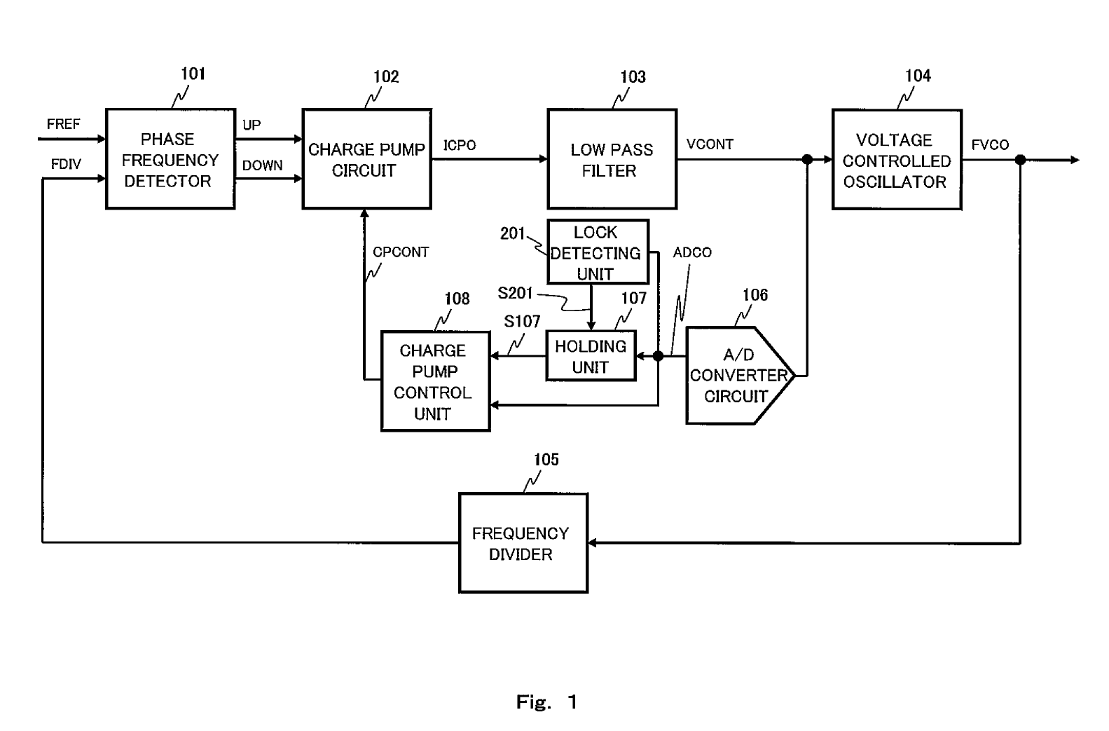

Hereinafter, a configuration of a PLL circuit according to Embodiment 1 of the present invention will be described with reference to FIG. 1.

FIG. 1 is a block diagram showing the configuration of the PLL circuit according to Embodiment 1 of the present invention. Referring to FIG. 1, the PLL circuit includes a phase frequency detector 101, a charge pump circuit 102, a low pass filter 103, a voltage controlled oscillator 104, a frequency divider 105, an analog/digital (A/D) converter circuit 106, a lock detecting unit 201, a holding unit 107, and a charge pump control unit 108.

The phase frequency detector 101 detects a phase difference and a frequency difference between a reference clock signal FREF and a feedback clock signal FDIV, and outputs an up-pulse signal UP and a down-pulse signal DOWN which are used for controlling the charge pump circuit 102 in accordance with the phase difference and the frequency difference. To be specific, when a phase of the feedback clock signal FDIV is delayed with respect to a phase of the reference clock signal FREF, or a frequency of the feedback clock signal FDIV is lower than a frequency of the reference clock signal FREF, the phase frequency detector 101 outputs an up-pulse signal UP with a pulse duration according to the phase difference and the frequency difference for increasing the frequency of the feedback clock signal FDIV. On the other hand, when a phase of the feedback clock signal FDIV is put forward with respect to a phase of the reference clock signal FREF, or a frequency of the feedback clock signal FDIV is higher than a frequency of the reference clock signal FREF, the phase frequency detector 101 outputs a down-pulse signal DOWN with a pulse duration according to the phase difference and the frequency difference for decreasing the frequency of the feedback clock signal FDIV.

The charge pump circuit 102 is configured to output a charge pump current ICPO which is a composite signal of the up-pulse signal UP and the down-pulse signal DOWN which are output from the phase frequency detector 101. In addition, the charge pump circuit 102 is configured to switch a current amount of the charge pump current ICPO between two levels which are a first current amount and a second current amount less than the first current amount, in accordance with a charge pump current amount control signal CPCONT output from the charge pump control unit 108. For example, as shown in FIG. 11 in Japanese Laid-Open Patent Application Publication No. Hei. 11-251902, the charge pump circuit 102 may include a first current source corresponding to the first current amount and a second current source corresponding to the second current amount, and may be configured to operate the first current source or the second current source in accordance with the charge pump current amount control signal CPCONT output from the charge pump control unit 108.

The low pass filter 103 smoothes the charge pump current ICPO from the charge pump circuit 102 and outputs an analog voltage signal VCONT. The voltage controlled oscillator 104 outputs an output clock signal FVCO with a frequency determined in accordance with the analog voltage signal VCONT from the low pass filter 103. The frequency divider 105 generates the feedback clock signal FDIV by dividing a frequency of the output clock signal FVCO from the voltage controlled oscillator 104 by a desired frequency dividing number and outputs it to the phase frequency detector 101. This results in the output clock signal FVCO which is synchronous with the reference clock signal FREF and has a frequency obtained by multiplying the frequency of the reference clock signal FREF by an inverse number of the frequency dividing number. When it is not necessary to change the frequency, the frequency divider 105 may be omitted.

The A/D converter circuit 106 converts the analog voltage signal VCONT output from the low pass filter 103 into a digital signal ADCO. A holding unit 107 holds the digital signal ADCO output from the A/D converter circuit 106. The charge pump control unit 108 compares a digital signal S107 (ADCO) (digital signal at a time point when a lock detection signal is input to the holding unit 107, hereinafter also referred to as lock digital signal) read from the holding unit 107 to the digital signal ADCO output from the A/D converter circuit 106. According to a result of the comparison, the charge pump control unit 108 outputs the charge pump current amount control signal CPCONT for switching the current amount of the charge pump current ICPO from the first current amount to the second current amount less than the first current amount.

The lock detecting unit 201 detects whether or not the feedback clock signal FDIV is locked to the reference clock signal FREF, and outputs a lock detection signal S201 when the lock is detected.

The holding unit 107 receives as inputs the digital signal ADCO output from the A/D converter circuit 106 and the lock detection signal S201, and holds the digital signal S107 from the A/D converter circuit 106, at a time point when the lock detection signal S201 is input from the lock detecting unit 201 to the holding unit 107.

The charge pump control unit 108 receives as inputs the lock digital signal S107 held in the holding unit 107 and the digital signal ADCO output from the A/D converter circuit 106, generates the charge pump current amount control signal CPCONT based on a result of comparison between the lock digital signal S107 and the digital signal ADCO and outputs the charge pump current amount control signal CPCONT to the charge pump circuit 102.

### [Holding Unit]

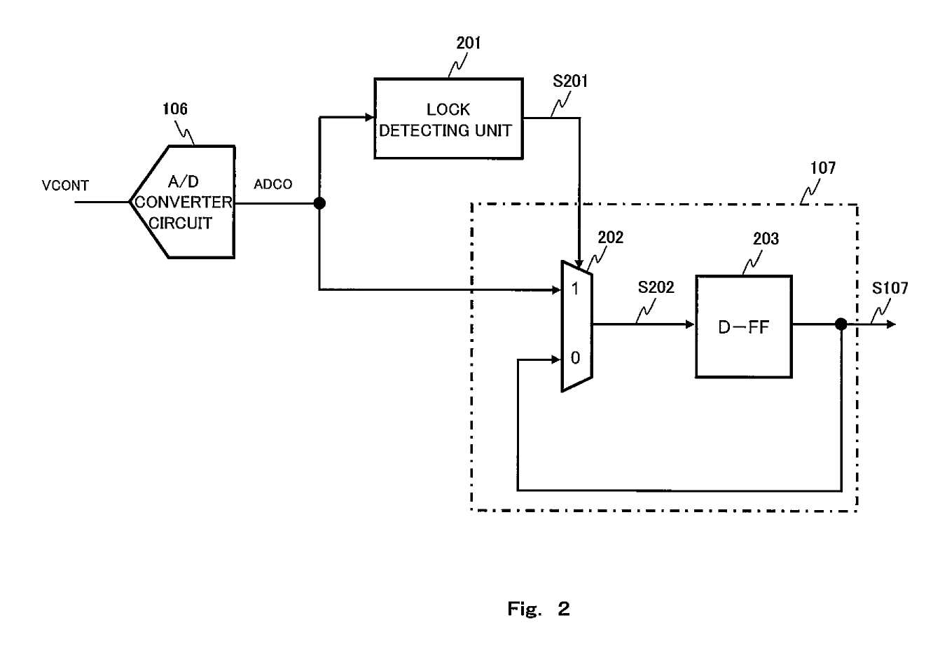

Hereinafter, a configuration of the holding unit 107 of FIG. 1 will be described with reference to FIG. 2.

FIG. 2 is a block diagram showing the configuration of the holding unit 107 of FIG. 1. Referring to FIG. 2, the holding unit 107 is configured to include a selector unit 202 and a D flip flop 203.

When the lock detection signal S201 is output from the lock detecting unit 201, this becomes a trigger, and the selector unit 202 sends as an output signal S202 the digital signal ADCO output from the A/D converter circuit 106, to the D flip flop 203. The output signal S202 is held in the D flip flop 203. To be specific, when a level of the lock detection signal S201 is active (1), the digital signal ADCO output from the A/D converter circuit 106 is sent to the D flip flop 203 via the selector unit 202 and held therein. On the other hand, when a level of the lock detection signal S201 is negative (0), the output of the D flip flop 203 is returned to an input of the D flip flop 203 via the selector unit 202. In other words, the digital signal ADCO held in the D flip flop 203 continues to be held. Thereafter, the D flip flop 203 continues to hold the digital signal ADCO as long as the lock detection signal 5201 is not output from the lock detecting unit 201 again. With this configuration, the holding unit 107 can hold the lock digital signal ADCO at a time point when the PLL circuit is locked.

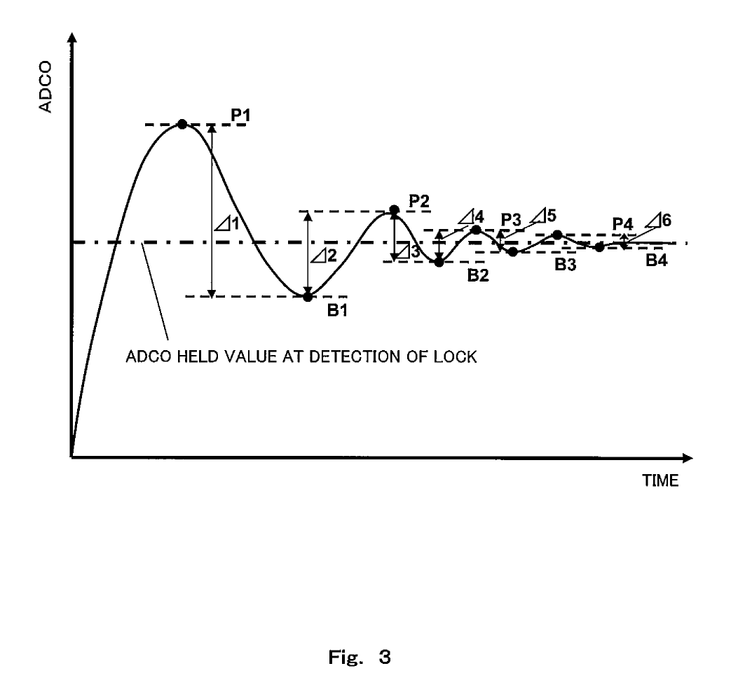

A lock detecting method in the lock detecting unit 201 will be described with reference to FIG. 3. FIG. 3 shows a change in the digital signal ADCO from when the PLL operation starts until the lock is detected. In a waveform shown in FIG. 3, peaks appearing from when the PLL operation starts are expressed sequentially as P1, P2, . . . P4, while bottoms appearing from when the PLL operation starts are expressed sequentially as B1, B2, . . . B4. When an absolute value of a difference between the peak P1 and the bottom B1 is Δ1, an absolute value of a difference between the peak P2 and the bottom B1 is Δ2, . . . , and an absolute value of a difference between the peak P4 and the bottom B3 is Δ6, the lock detecting unit 201 detects that the PLL circuit is locked when the absolute value of the difference between the peak and the bottom is not more than a reference value. The reference value is an arbitrary value.

### [Charge Pump Control Unit]

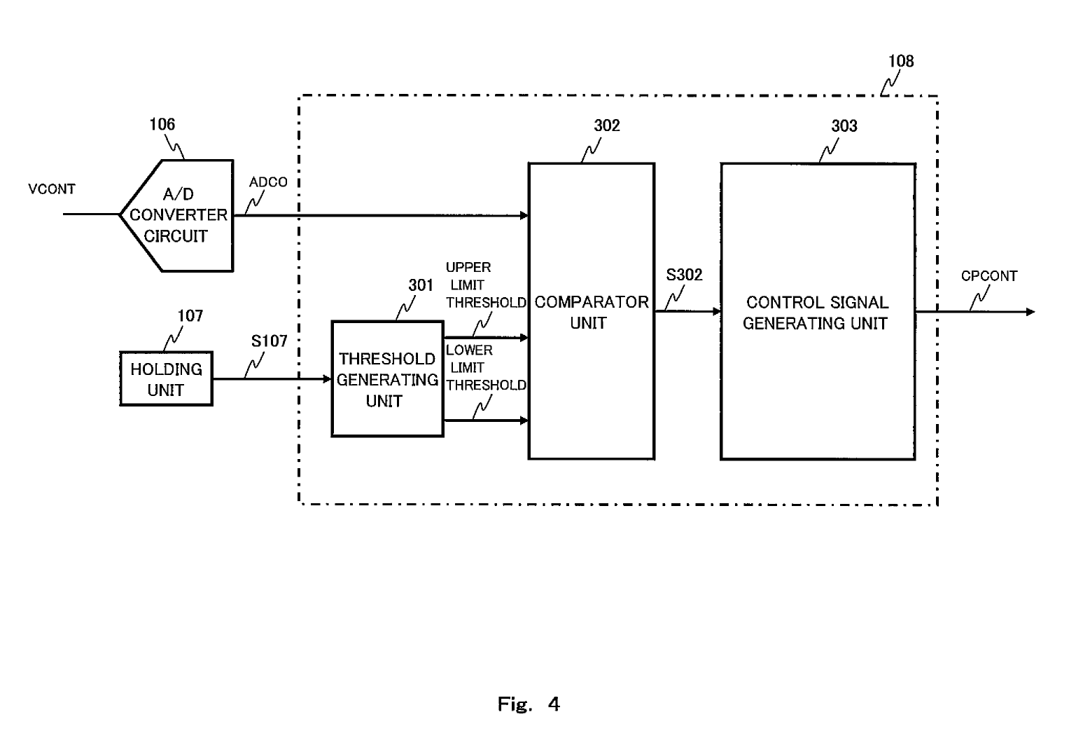

A configuration of the charge pump control unit 108 shown in FIG. 1 will be described with reference to FIG. 4.

FIG. 4 is a block diagram showing a configuration of the charge pump control unit 108 of FIG. 1.

Referring to FIG. 4, the charge pump control unit 108 includes a threshold generating unit 301 for generating an upper limit threshold and a lower limit threshold based on the lock digital signal S107 (ADCO) output from the holding unit 107, a comparator unit 302 for comparing the upper limit threshold and the lower limit threshold generated in the threshold generating unit 301 to the digital signal ADCO output from the A/D converter circuit 106, and a control signal generating unit 303 for generating the charge pump current amount control signal CPCONT for decreasing the charge pump current amount stepwisely, based on the output signal S302 received as an input from the comparator unit 302.

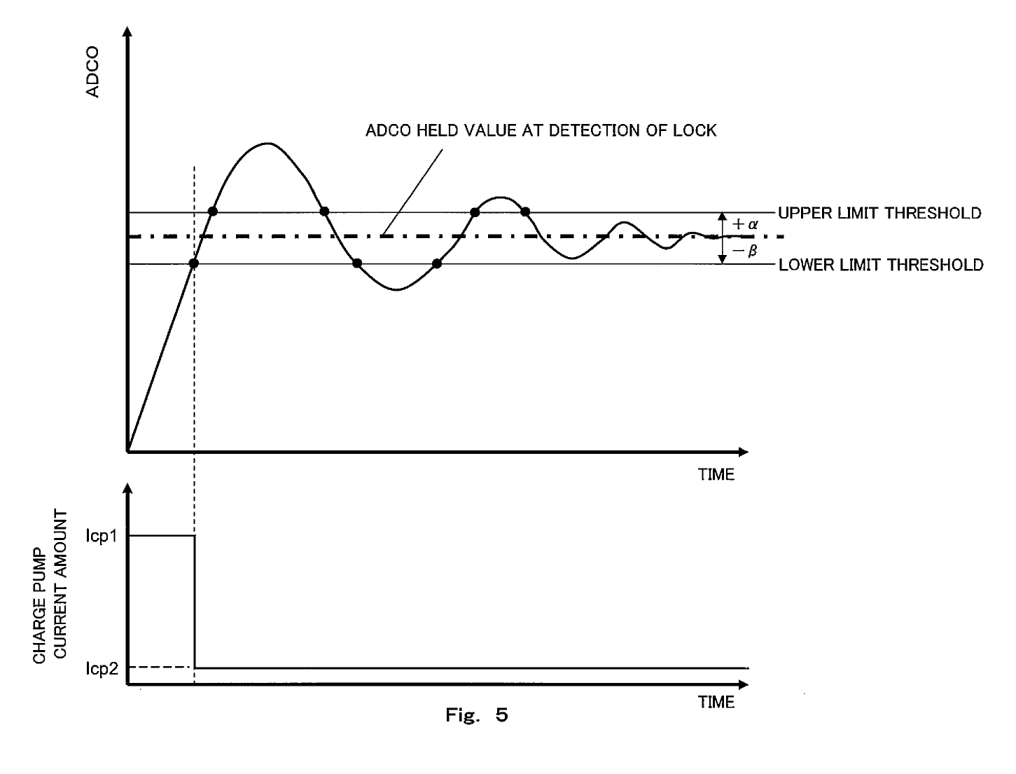

Next, a switching operation of the charge pump current amount performed by the charge pump control unit 108 of FIG. 1 will be described with reference to FIG. 5.

FIG. 5 is a view showing a binary switching of a charge pump current performed by the charge pump control unit 108 of FIG. 4. When the feedback clock signal FDIV is locked to the reference clock signal FREF in a first PLL operation, the lock is detected by the lock detecting unit 201, and the D flip flop 203 in the holding unit 107 holds the lock digital signal ADCO. The charge pump control unit 108 causes the threshold generating unit 301 to generate as the upper limit threshold, a value obtained by adding a variable a to the lock digital signal ADCO held in the holding unit 107, and generates as the lower limit threshold, a value obtained by subtracting a variable β from the lock digital signal ADCO held in the holding unit 107. The variable α and the variable β can be set as desired by a register, or the like. Hereinafter, a range from the lower limit threshold to the upper limit threshold is referred to as a lock detection range. A fact that the digital signal ADCO converges within the lock detection range means that the lock similar to the lock in the first PLL operation is detected.

In the second and following PLL operation, the charge pump control unit 108 causes the comparator unit 302 to compare the digital signal ADCO output from the A/D converter circuit 106 to the upper limit threshold and the lower limit threshold generated in the threshold generating unit 301. Referring to FIG. 5, in a case where the digital signal ADCO starts rising from a digital value (minimum value) corresponding to 0V, the charge pump control unit 108 generates a charge pump current amount control signal CPCONT for switching the charge pump current amount from a first current amount Icp1 to a second current amount Icp2 (<Icp1) less than the first current amount Icp1 when the digital signal ADCO becomes equal to the lower limit threshold first (reaches (falls into) the lock detection range). Although not shown, in a case where the digital signal ADCO starts falling from a digital value (maximum value) corresponding to a power supply voltage, the charge pump control unit 108 generates the charge pump current amount control signal CPCONT for switching the charge pump current amount from the first current amount Icp1 to the second current amount Icp2 when the digital signal ADCO becomes equal to the upper limit threshold first (it reaches the lock detection range).

The charge pump control unit 108 is configured to decrease the charge pump current amount stepwisely, when the digital signal ADCO output from the A/D converter circuit 106 falls first into the lock detection range from the lower limit threshold to the upper limit threshold including the held value of the lock digital signal ADCO in the first PLL operation. As a result, the PLL circuit of FIG. 1 can obtain an optimal timing when the charge pump current amount is reduced stepwisely to achieve reduction of the lock-up time and reduction of the reference leak, irrespective of an IC operation condition such as a temperature and a power supply voltage. Since the charge pump current amount is controlled by the digital circuit rather than the analog circuit, the control is stabilized, and area reduction and electric power consumption reduction because of progress of a process for miniaturized constituents are expected.

### Embodiment 2

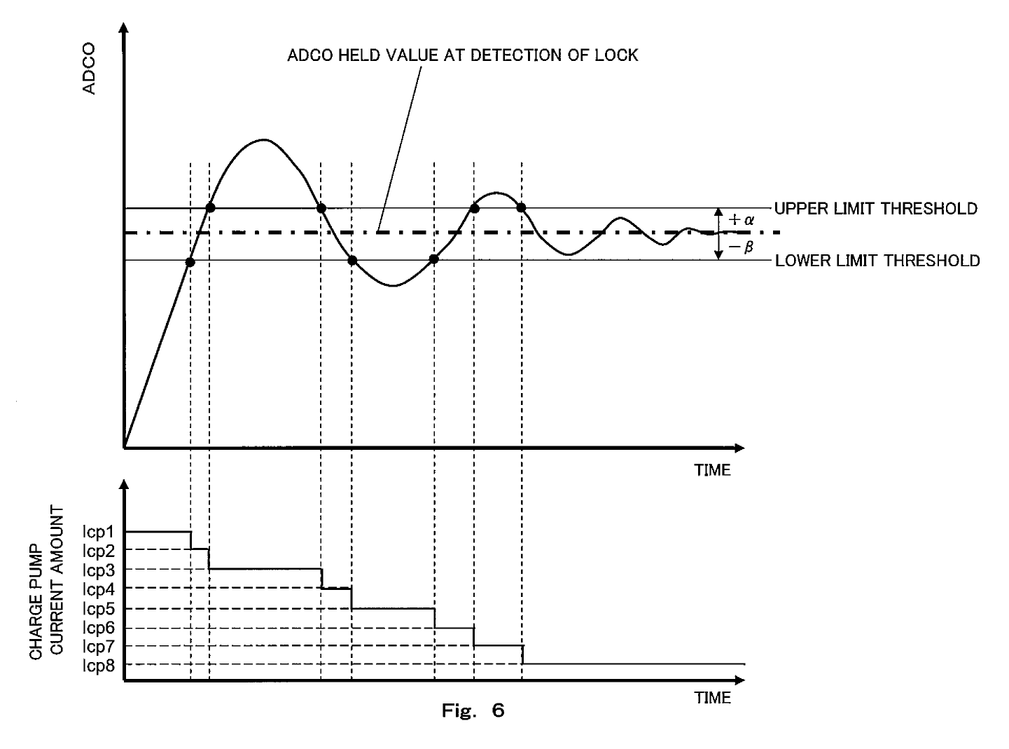

Hereinafter, a PLL circuit according to Embodiment 2 of the present invention will be described with reference to FIG. 6.

The configuration of the PLL circuit of Embodiment 2 is identical to that of the PLL circuit of Embodiment 1 of FIG. 1 except that the charge pump current amount is switched from an initial current amount to a current amount less than the initial current amount in multi-levels which are three levels or more, after a time point when the digital signal ADCO first becomes equal to the lower limit threshold or the upper limit threshold.

To be specific, as shown in FIG. 6, the charge pump control unit 108 switches the current amount from the first current amount Icp1 to the second current amount Icp2 less than the first current amount Icp1 when the digital signal ADCO becomes equal to the lower limit threshold (when it reaches (falls into) the lock detection range). Following this, the charge pump control unit 108 switches the current amount from the second current amount Icp2 to a third current amount Icp3 when the digital signal ADCO becomes equal to the upper limit threshold (when it falls outside the lock detection range).

As described above, the charge pump control unit 108 is configured to switch the charge pump current amount in the order of the first current amount Icp1, the second current amount Icp2, . . . an eighth current amount Icp8 (Icp1>Icp2> . . . Icp8) every time the digital signal ADCO becomes equal to the lower limit threshold or the upper limit threshold (every time it falls outside the lock detection range or reaches the lock detection range). Since the charge current amount is not reduced rapidly but gradually reduced in multi-levels which are three levels or more according to stabilization of a lock state of the PLL circuit. Therefore, in addition to the advantages of Embodiment 1, the operation of the PLL circuit can be more stabilized.

### Embodiment 3

Hereinafter, a PLL circuit according to Embodiment 3 of the present invention will be described.

The configuration of the PLL circuit of Embodiment 3 (including the holding unit 107, and charge pump control unit 108) is identical to that of the PLL circuit of Embodiment 1 shown in FIG. 1, except that the holding unit 107 is adapted to hold an arbitrary digital signal ADCO rather than the lock digital signal ADCO in the first PLL operation. Since the holding unit 107 is implemented as a digital circuit, the value held in the holding unit 107 can be set as desired by a register, etc. With this configuration, an optimal timing when the charge pump current amount is reduced can be easily set.

### Embodiment 4

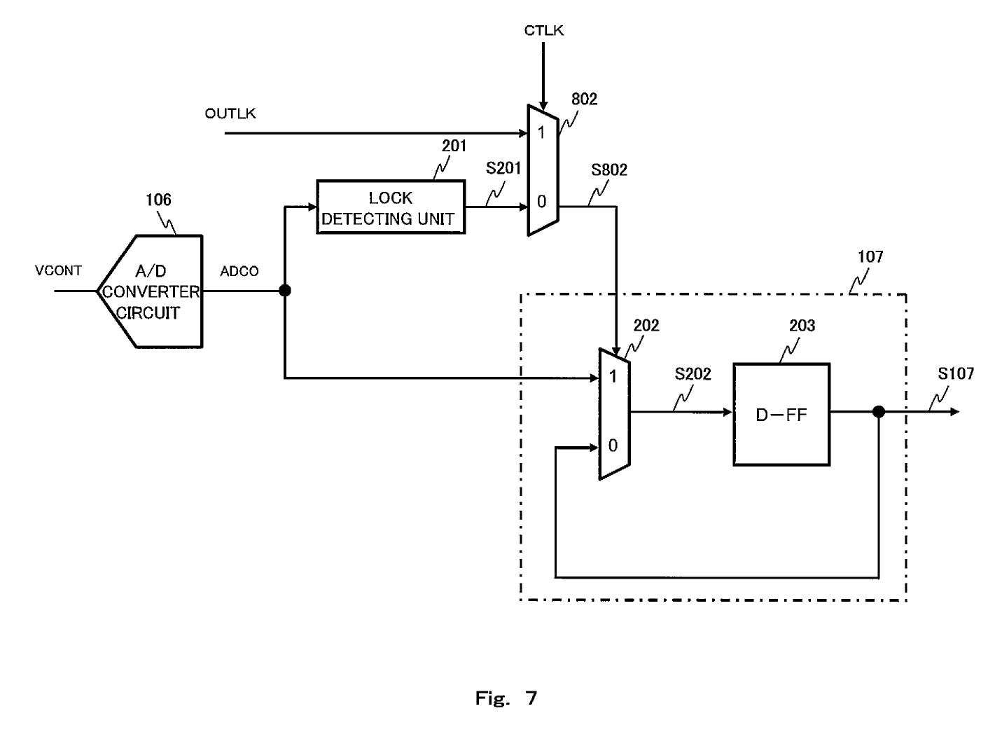

Hereinafter, a PLL circuit according to Embodiment 4 of the present invention will be described with reference to FIG. 7.

Referring to FIG. 7, the configuration of the PLL circuit of Embodiment 4 is identical to that of the PLL circuit of Embodiment 1 shown in FIG. 1, except that a selector unit 802 is incorporated into the PLL circuit of Embodiment 4.

The selector unit 802 is configured to select an outside lock detection signal OUTLK supplied from outside the PLL circuit or the lock detection signal S201 output from the lock detecting unit 201 within the PLL circuit in accordance with a level of a control signal CTLK and outputs the selected lock detection signal. To be specific, the selector unit 802 selects the outside lock detection signal OUTLK and outputs it as a select control signal 5802 when the control signal CTLK is High level (1), while the selector unit 802 selects the lock detection signal S201 output from the lock detecting unit 201 and outputs it as the select control signal 5802 when the control signal CTLK is Low level (0).

The select control signal S802 is used as a control signal in the selector unit 202 of the holding unit 107. Receiving the select control signal S802 from the selector unit 802, the selector unit 202 sends the digital signal ADCO output from the A/D converter circuit 106, to the D flip flop 203. Thereafter, the D flip flop 203 continues to hold a current state as long as the selector unit 802 does not output the select control signal S802. Alternatively, the timing when the digital signal ADCO is held in the holding unit 107 may be decided using only the outside lock detection signal OUTLK without using the lock detecting unit 201.

With the above configuration, the timing when the digital signal ADCO is held in the holding unit 107 can be decided more flexibly using the outside lock detection signal OUTLK or the lock detection signal S201 output from the lock detecting unit 201.

In accordance with the present invention, it is possible to achieve reduction of the lock-up time and reduction of the reference leak in a well-balanced manner, and therefore, the present invention is useful in improvement of performance of the PLL circuit.

As this invention may be embodied in several forms without departing from the spirit of essential characteristics thereof, the present embodiment is therefore illustrative and not restrictive, since the scope of the invention is defined by the appended claims rather than by the description preceding them, and all changes that fall within metes and bounds of the claims, or equivalence of such metes and bounds thereof are therefore intended to be embraced by the claims.

What is claimed is:

1. A PLL circuit comprising:
a phase frequency detector configured to output a phase frequency difference signal with a pulse duration according to a phase difference and a frequency difference between a reference clock signal and a feedback clock signal according to an output clock signal;
a charge pump circuit configured to output a charge pump current which is an output current according to the phase frequency difference signal and reduce a charge pump current amount in accordance with a charge pump current amount control signal for reducing the charge pump current amount stepwisely;
a low pass filter configured to smooth the charge pump current and output a control voltage generated by smoothing the charge pump current;
a voltage controlled oscillator configured to output the output clock signal with an oscillating frequency according to the control voltage;
an analog/digital converter circuit configured to convert the control voltage of an analog signal into a digital signal and output the digital signal;
a lock detecting unit configured to detect whether or not the feedback clock signal is locked to the reference clock signal and output a lock detection signal when detecting a lock of the reference clock signal and the feedback clock signal;
a holding unit configured to hold the digital signal from the analog/digital converter circuit, when receiving the lock detection signal from the lock detecting unit as an input; and
a charge pump control unit configured to generate the charge pump current amount control signal based on a result of comparison between the digital signal held in the holding unit at a point when the lock detection signal is input to the holding unit, and the digital signal output from the analog/ digital converter circuit to the charge pump control unit, and output the charge pump current amount control signal to the charge pump circuit.

2. The PLL circuit according to claim 1,
wherein the charge pump control unit includes:
a threshold generating unit configured to generate an upper limit threshold which is larger than a value of the digital signal held in the holding unit at a point when the lock detection signal is input to the holding unit, and a lower limit threshold smaller than the held value of the digital signal;
a comparator unit configured to detect whether or not the digital signal output from the analog/digital converter circuit falls within a lock detection range from the lower limit threshold to the upper limit threshold; and
a control signal generating unit configured to generate the charge pump current amount control signal for switching from a first current amount which is an initial current amount to a second current amount less than the first current amount, from when the comparator unit detects that the digital signal output from the analog/digital converter circuit reaches first the lock detection range.

3. The PLL circuit according to claim 2,
wherein the control signal generating unit is configured to generate the charge pump current amount control signal for stepwisely reducing the charge pump current from an initial current amount to a current amount less than the initial current amount, every time the comparator unit detects that the digital signal from the analog/digital converter circuit falls outside the lock detection range or reaches the lock detection range, from when the comparator unit detects that the digital signal from the analog/digital converter circuit reaches first the lock detection range.

4. The PLL circuit according to claim 1,
wherein the digital signal held in the holding unit at a point when the lock detection signal is input to the holding unit is set arbitrarily.

5. The PLL circuit according to claim 1, comprising:
a selector unit configured to select an outside lock detection signal from outside or the lock detection signal from the lock detecting unit in accordance with a predetermined select control signal, and output the selected lock detection signal to the holding unit.
